(19) United States
(12) Patent Application Publication
(10) Pub. No.: US 2006/0043368 A1
(43) Pub. Date: Mar. 2, 2006

(54) Flash cell structures and methods of formation

(75) Inventors: Di Li, Boise, ID (US); Chun Chen, Boise, ID (US); Graham Wolstenholme, Boise, ID (US); Sukesh Sandhu, Boise, ID (US); Xianfeng Zhou, Meridian, ID (US)

Correspondence Address: Leffert Jay & Polglaze, P.A., P.O. Box 581009, Minneapolis, MN, 55458-1009, US

(73) Assignee: Micron Technology, Inc.

(21) Appl. No.: 11/218,101

(22) Filed: Sep. 1, 2005

Related U.S. Application Data
(62) Division of application No. 10/930,323, filed on Aug. 31, 2004.

(51) Int. Cl. H01L 27/108

(52) U.S. Cl. 257/68

(57) ABSTRACT

Methods of fabrication and flash memory structures eliminate process steps while increasing capacitive coupling between floating gates and control gates of the memory cells. A thick floating gate is deposited early in the process, and a height and width of the floating gate is controlled with deposition and etching or the use of spacers.

### RELATED APPLICATION

This Application is a Divisional of U.S. application Ser. No. 10/930,323, titled “FLASH CELL STRUCTURES AND METHODS OF FORMATION,” filed Aug. 31, 2003, (pending) which is commonly assigned and incorporated herein by reference.

### FIELD

The present invention relates generally to integrated circuit devices, and in particular the present invention relates to flash cell structures and methods of formation.

### BACKGROUND

Memory devices are typically provided as internal storage areas in a computer. The term memory identifies data storage that comes in the form of integrated circuit chips. In general, memory devices contain an array of memory cells for storing data, and row and column decoder circuits coupled to the array of memory cells for accessing the array of memory cells in response to an external address.

One type of memory is a non-volatile memory known as Flash memory. A flash memory is a type of EEPROM (electrically-erasable programmable read-only memory) that can be erased and reprogrammed in blocks. Many modern personal computers (PCs) have their BIOS stored on a flash memory chip so that it can easily be updated if necessary. Such a BIOS is sometimes called a flash BIOS. Flash memory is also popular in wireless electronic devices because it enables the manufacturer to support new communication protocols as they become standardized and to provide the ability to remotely upgrade the device for enhanced features.

A typical flash memory comprises a memory array that includes a large number of memory cells arranged in row and column fashion. Each of the memory cells includes a floating-gate field-effect transistor capable of holding a charge. The cells are usually grouped into blocks. Each of the cells within a block can be electrically programmed in a random basis by charging the floating gate. The charge can be removed from the floating gate by a block erase operation. The data in a cell is determined by the presence or absence of the charge in the floating gate.

Flash memory typically utilizes one of two basic architectures known as NOR flash and NAND flash. The designation is derived from the logic used to read the devices. In NOR flash architecture, a column of memory cells are coupled in parallel with each memory cell coupled to a bit line. In NAND flash architecture, a column of memory cells are coupled in series with only the first memory cell of the column coupled to a bit line.

Memory device fabricators are continuously seeking to reduce the size of the devices. Smaller devices facilitate higher productivity and reduced power consumption. However, as device sizes become smaller, resistance of the various conductors becomes an ever-increasing problem. High resistance can lead to slower performance. One solution is to utilize materials having higher conductivity.

Flash devices need high capacitive coupling between the control gate and the floating gate because of performance requirements. A traditional flash structure is shown in several stages of fabrication in FIGS. 1A, 1B, and 1C. Shallow trench isolation (STI) techniques, which are known in the art, are used to form the structure shown in FIG. 1A, which has a silicon substrate 105, tunnel oxide layer 110, and a first polysilicon layer 115, often called poly 1a. A second polysilicon layer, often called poly 1b, is shown deposited over the STI and poly 1a structure in FIG. 1B. Varying the thickness of the poly 1b layer and the width of the poly 1b layer can control the capacitive coupling ratio of the structure, as is shown in FIG. 1C. The height and width variation of the poly 1b layer is controlled by depositing the second polysilicon layer and DUV patterning to control the height and width of poly 1b to achieve a high coupling ratio.

Recently, an approach eliminating deep ultra-violet (DUV) patterning by performing an oxide etch back was proposed. This approach reduces costs, but capacitive coupling degrades because the width of the floating gate is reduced. Proposed remedies such as increasing the poly height are limited due to the increase in gate resistance with such a proposal, as well as manufacturing difficulties and scaling issues.

For the reasons stated above, and for other reasons stated below which will become apparent to those skilled in the art upon reading and understanding the present specification, there is a need in the art for improved fabrication techniques, and improved coupling ratios in flash memory structures.

### SUMMARY

The above-mentioned problems with flash memory structures and other problems are addressed by the present invention and will be understood by reading and studying the following specification.

In one embodiment, a method of fabricating an array of floating gate memory cells includes forming a tunnel oxide layer over a number of columns surrounded by shallow trenches, forming a thick polysilicon floating gate over the tunnel oxide layer, forming a set of spacers at the edge of each floating gate, forming a dielectric layer over the trenches, the spacers, and the floating gates, and forming a control gate over the dielectric layer.

In another embodiment, a method of fabricating an array of floating gate memory cells includes forming a tunnel oxide layer over a number of columns surrounded by shallow trenches, forming a thick polysilicon floating gate over the tunnel oxide layer, patterning a second polysilicon layer to control height and width of the floating gate, forming a dielectric layer over the trenches and the floating gates, and forming a control gate over the dielectric layer.

In still another embodiment, a method of controlling a coupling ratio in a flash memory cell includes controlling a height and a width of a floating gate of the flash memory cell.

In yet another embodiment, a floating gate memory cell array includes a number of shallow trenches filled with a dielectric material, a number of columns surrounded by the shallow trenches, a tunnel oxide layer at the top of each column, a thick polysilicon floating gate over each tunnel oxide layer, a set of spacers at an edge of each floating gate, the spacers over the dielectric material of the trenches, a dielectric layer over the trenches, the spacers, and the floating gates, and a control gate over the dielectric layer.

In still another embodiment, an array of floating-gate field-effect transistors includes two or more columns of the floating-gate field-effect transistors. Each field-effect transistor of a column includes a tunnel oxide, a thick polysilicon floating gate formed over the tunnel oxide, spacers at the edge of the floating gate, a dielectric layer formed over the spacers and the floating gate, and a control gate formed over the dielectric layer.

Other embodiments are described and claimed.

### BRIEF DESCRIPTION OF DRAWINGS

FIGS. 1A-1C are cross-sectional views of a portion of a prior art memory array;

FIGS. 2A-2H are cross-sectional views of a portion of a memory array during various stages of fabrication according to one embodiment of the invention;

FIGS. 3A-3C are cross-sectional views of a portion of a memory array during various stages of fabrication according to another embodiment of the present invention; and

FIG. 4 is a functional block diagram of a basic flash memory device, coupled to a processor, in accordance with an embodiment of the invention.

### DETAILED DESCRIPTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention.

The terms wafer and substrate used previously and in the following description include any base semiconductor structure. Both are to be understood as including silicon-on-sapphire (SOS) technology, silicon-on-insulator (SOI) technology, thin film transistor (TFT) technology, doped and undoped semiconductors, epitaxial layers of silicon supported by a base semiconductor, as well as other semiconductor structures well known to one skilled in the art. Furthermore, when reference is made to a wafer or substrate in the following description, previous process steps may have been utilized to form regions/junctions in the base semiconductor structure. The following detailed description is, therefore, not to be taken in a limiting sense, and the scope of the present invention is defined only by the appended claims and their equivalents.

The following detailed description is, therefore, not to be taken in a limiting sense, and the scope of the present invention is defined only by the appended claims, along with the full scope of equivalents to which such claims are entitled.

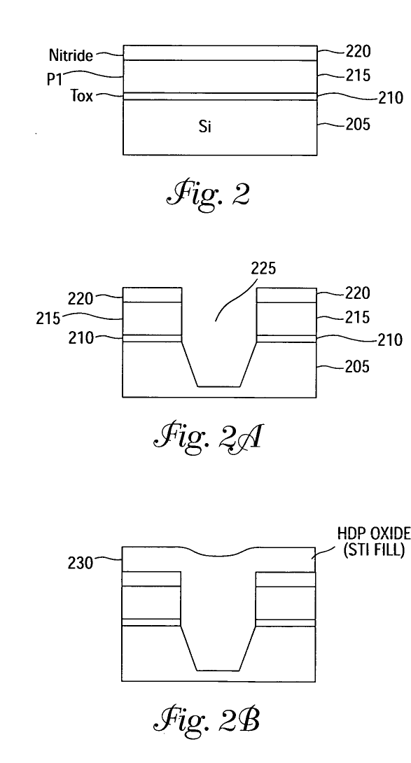

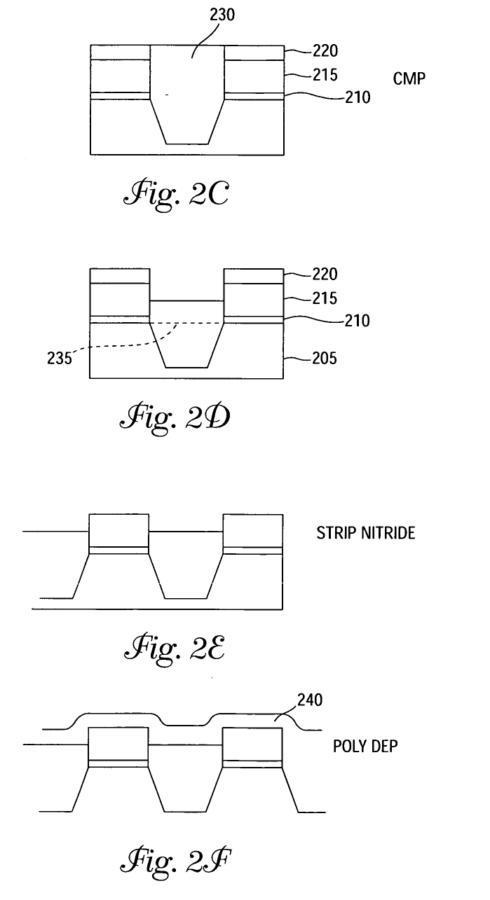

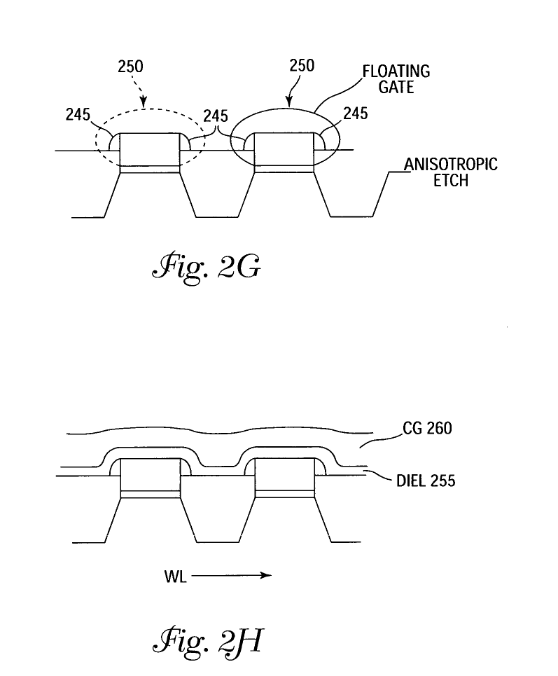

FIGS. 2A-2H generally depict a method of forming a portion of a memory array in accordance with an embodiment of the invention. FIG. 2A depicts a portion of the memory array after several processing steps have occurred. Formation of the structure depicted in FIG. 2A is well known and will not be detailed herein. In general, FIG. 2A depicts several stacks of layers that will form word lines of the memory array. The stacks include a tunnel dielectric 210 is formed on a substrate 205. Tunnel dielectric 210 is generally a silicon oxide, but may be any dielectric material. Some specific examples include silicon oxides (SiO/SiQ₂), silicon nitrides (SiN/Si₂N/Si₃N₄) and silicon oxynitrides (SiOₓN_{y}). For one embodiment, substrate 205 is a P-type silicon substrate. A first polysilicon layer 215 is formed over the tunnel dielectric 210. First polysilicon layer 215 will become the floating gate for this embodiment. First polysilicon layer 215 may be conductively doped. An example would be an n-type polysilicon layer. In one embodiment, the first polysilicon layer 215 is a thick polysilicon layer. In this embodiment, the polysilicon layer 215 is deposited to a thickness of approximately 500 to 1500 Angstroms.

A nitride layer 220 is formed over the first polysilicon layer 215. Trench 225 is formed by photolithographic etching to form shallow trenches. Shallow trench isolation (STI) methods are known in the art and will not be described further herein. Following STI, an STI fill is performed, as is shown in FIG. 2B. STI fill in one embodiment is an oxide such as oxide 230 laid down by high density plasma deposition. The planarized structure after a chemical mechanical polish step is shown in FIG. 2C.

FIG. 2D depicts the structure after a buffered oxide dipback etch (which is a wet etch over a dry etch) to recess the oxide 230 back to a level approximately 400-600 Angstroms above the top surface 235 of silicon substrate 205. The top of the remaining oxide is in this embodiment above top level of the tunnel oxide 210. After a nitride strip, the resultant structure is shown in FIG. 2E.

In the present embodiment, the floating gate deposition required by the prior art process is not performed, since the polysilicon that will form the floating gate is already present in the structure. Instead, a second polysilicon spacer layer 240 is deposited as is shown in FIG. 2F. The spacer layer 240 is etched using, for example, an anisotropic etch to leave the structure shown in FIG. 2G, with floating gates 250 comprising polysilicon 215 and spacers 245. The structure is completed with an interpolysilicon dielectric deposition layer 255 followed by deposition of a second polysilicon layer 260 as a control gate, as is shown in FIG. 2H.

From the structure of FIG. 2G, several options for completion of the structure are available. In one embodiment, a simple mask is used to open up the periphery of the structure and etch out the polysilicon prior to oxide-nitride-oxide processing. The requires an extra mask step. In another embodiment, oxide-nitride-oxide processing is performed, and a simple mask is used to etch out the ONO and the polysilicon from the periphery, eliminating the need for the extra mask step. While either process is acceptable, the process that eliminates the extra mask step requires fewer processing steps, and subjects the structure to less stress from processing.

Oxide-nitride-oxide layer 255 may also be any dielectric layer. Other dielectric materials may be substituted for the ONO, such as tantalum oxide, barium strontium titanate, silicon nitride and other materials providing dielectric properties.

In traditional prior art fabrication, a thinner first polysilicon layer is used, typically on the order of 200-400 Angstroms. The process of formation is similar until after the nitride strip process. At this point in typical prior art fabrication techniques, floating gate polysilicon deposition followed by a photolithographic etch is performed, using a floating gate mask. In the present embodiments, the separate deposition of a floating gate polysilicon layer is eliminated, since the thick polysilicon deposition discussed above with respect to FIG. 2A forms the floating gate. The processes of the present embodiments provide an increased active area with fewer steps.

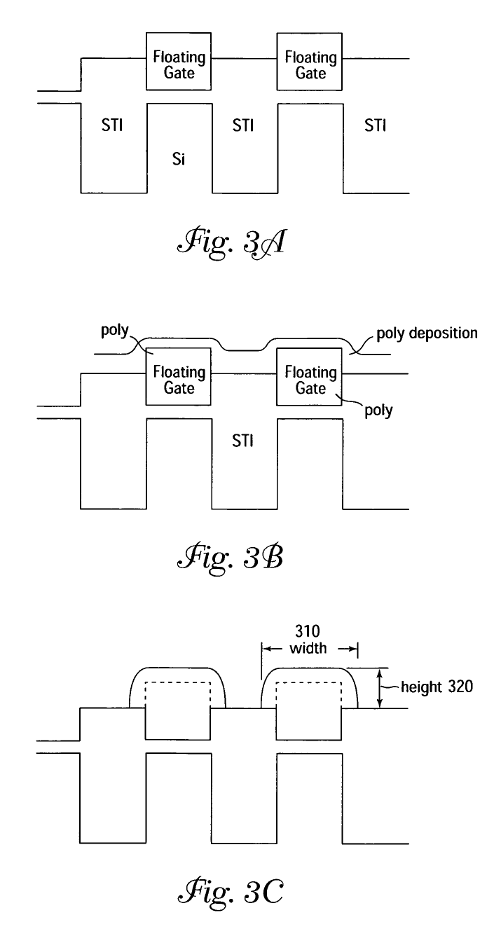

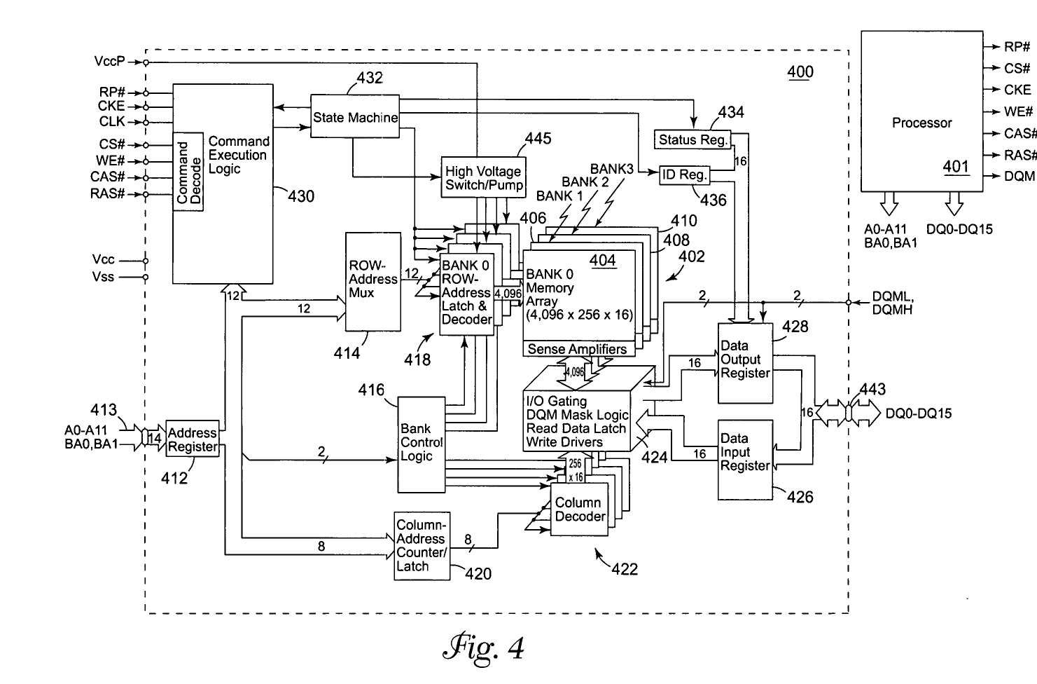

FIG. 3 depicts an embodiment of another process of increasing the coupling ratio of the structure of FIG. 2F. In FIG. 3, after the second, coupling ratio control, polysilicon layer 240 is deposited, polysilicon deposition and dry etching is used to control the width 310 and height 320 of the coupling ratio control polysilicon layer, and ultimately to control the coupling ratio. By varying the deposition thickness of the polysilicon layer 240, and over etch rates or multiple cycles of deposition and dry etching, the width and height of the polysilicon layer 240 left after processing can be controlled effectively. This provides better capacitive coupling between the control gate and the floating gate, thereby improving performance over the approach eliminating DUV processing. The embodiment allows adjustment and control of the height of the gate stack conveniently. The structure is easier to manufacture than traditional structures, and is scalable. In contrast to traditional fabrication processing, the embodiment provides similar performance but provides large cost reductions by elimination of the DUV patterning of the floating gate.

In the process and structure shown in FIG. 3, after the STI oxide etch back, another poly layer is deposited followed by a polysilicon dry etch to recover coupling ratio since both width and height of the poly floating gate can be adjusted easily by varying the poly layer thickness, overetch rate, of performing multiple deposition and dry etch steps according to device performance requirements.

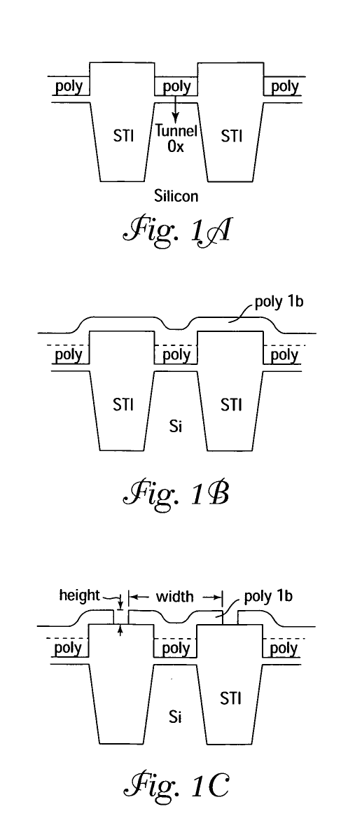

Advantages of the embodiments of FIG. 2 include elimination of one floating gate mask process, reducing costs, and an increased active area due to the spacers. Advantages of the embodiments of FIG. 3 include cost reduction over traditional processing by elimination of DUV patterning to form floating gates, and improved capacitive coupling over the approach of FIG. 1.

FIG. 4 is a functional block diagram of a basic flash memory device 400 that is coupled to a processor 401. The memory device 400 and the processor 401 may form part of an electronic system. The memory device 400 has been simplified to focus on features of the memory that are helpful in understanding the present invention. The memory device 400 includes an array of non-volatile memory cells 402. The memory array 402 includes memory cells formed in accordance with an embodiment of the invention.

Each memory cell is located at an intersection of a word line and a local bit line. The memory array 402 is arranged in rows and columns, with the rows arranged in blocks. A memory block is some discrete portion of the memory array 402. Individual word lines generally extend to only one memory block while bit lines may extend to multiple memory blocks. The memory cells generally can be erased in blocks. Data, however, may be stored in the memory array 402 separate from the block structure.

The memory array 402 is arranged in a plurality of addressable banks. In one embodiment, the memory contains four memory banks 404, 406, 408 and 410. Each memory bank contains addressable sectors of memory cells. The data stored in the memory can be accessed using externally provided location addresses received by address register 412 from processor 401 on address lines 413. The addresses are decoded using row address multiplexer circuitry 414. The addresses are also decoded using bank control logic 416 and row address latch and decode circuitry 418.

To access an appropriate column of the memory, column address counter and latch circuitry 420 couples the received addresses to column decode circuitry 422. Circuit 424 provides input/output gating, data mask logic, read data latch circuitry and write driver circuitry. Data is input through data input registers 426 and output through data output registers 428. This bi-directional data flow occurs over data (DQ) lines 443.

Command execution logic 430 is provided to control the basic operations of the memory device including memory read operations. A state machine 432 is also provided to control specific operations performed on the memory arrays and cells. A high voltage switch and pump circuit 445 is provided to supply higher voltages during erase and write operations. A status register 434 and an identification register 436 can also be provided to output data.

The memory device 400 can be coupled to an external memory controller, or processor 401, to receive access commands such as read, write and erase command. Other memory commands can be provided, but are not necessary to understand the present invention and are therefore not outlined herein. The memory device 400 includes power supply inputs Vss and Vcc to receive lower and upper voltage supply potentials.

As stated above, the flash memory device 401 has been simplified to facilitate a basic understanding of the features of the memory device. A more detailed understanding of flash memories is known to those skilled in the art. As is well known, such memory devices 401 may be fabricated as integrated circuits on a semiconductor substrate. The memory cells described above are used in various embodiments in the basic memory array or system structure described in FIG. 4.

### CONCLUSION

Memory cell structures and methods of fabrication have been described that include controlling the coupling ratio between the floating gate and the control gate, cost reduction in processing, and elimination of some fabrication processes. The embodiments of the present invention remove processing steps and subject the structure to less processing, reducing costs, but also improving control of capacitive coupling in the memory structure, and increasing active area of the resulting structures.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed:

1. An array of floating-gate field-effect transistors, comprising:
two or more columns of the floating-gate field-effect transistors, each field-effect transistor of a column comprising:
a tunnel oxide;
a thick polysilicon floating gate formed over the tunnel oxide;
spacers at the edge of the floating gate;
a dielectric layer formed over the spacers and the floating gate; and
a control gate formed over the dielectric layer.

2. The array of claim 1, wherein the floating gate is approximately 500-1500 Angstroms thick.

3. The array of claim 1, wherein the spacers are formed of polysilicon.

4. The array of claim 1, and further comprising:
a plurality of shallow trenches, a trench located between respective field-effect transistors.

5. The array of claim 4, wherein each of the plurality of shallow trenches is filled with a dielectric.

6. The array of claim 1, wherein the control gate is positioned over the floating gate.

7. The array of claim 1, wherein the dielectric layer is patterned to control a coupling ratio between the floating gate and the control gate.

8. The array of claim 1, wherein the dielectric layer has a thickness and width to control coupling between the floating gate and the control gate.

9. A floating gate memory cell array, comprising:
a plurality of shallow trenches filled with a dielectric material;
a plurality of columns surrounded by the plurality of shallow trenches;
a tunnel oxide layer at the top of each column;
a thick polysilicon floating gate over each tunnel oxide layer;
a set of spacers at an edge of each floating gate, the spacers over the dielectric material of the trenches;
a dielectric layer over the trenches, the spacers, and the floating gates; and
a control gate over the dielectric layer.

10. The floating gate memory cell array of claim 9, wherein the floating gate layer is approximately 500-1500 Angstroms thick.

11. The floating gate memory cell array of claim 9, wherein the spacers are formed of polysilicon.

12. The floating gate memory cell array of claim 9, wherein the control gate is positioned over the floating gate.

13. The floating gate memory cell array of claim 9, wherein the dielectric layer is patterned to control a coupling ratio between the floating gate and the control gate.

14. The floating gate memory cell array of claim 9, wherein the dielectric layer has a thickness and width to control coupling between the floating gate and the control gate.

15. A floating gate memory array formed by the process comprising:
forming a tunnel oxide layer over a plurality of columns surrounded by a plurality of shallow trenches;
forming a thick polysilicon floating gate over the tunnel oxide layer;
forming a set of spacers at the edge of each floating gate;
forming a dielectric layer over the trenches, the spacers, and the floating gates; and
forming a control gate over the dielectric layer.

16. The floating gate memory array of claim 15, wherein the floating gate layer is formed to a thickness of approximately 500-1500 Angstroms.

17. The floating gate memory array of claim 15, wherein forming a set of spacers comprises:
depositing a spacer layer of polysilicon over the trenches and the thick polysilicon layer; and
etching the spacer layer to remove all spacer polysilicon except a portion at edges of each floating gate.

18. The floating gate memory array of claim 15, and formed by the further process comprising:
controlling a coupling ratio between the floating gate and the control gate.

19. The floating gate memory array of claim 18, wherein controlling a coupling ratio comprises:
patterning the spacer layer over the floating gate to increase an active area of the floating gate.

20. A non-volatile memory device, comprising:
an array of non-volatile floating-gate memory cells arranged in rows and columns; and
control circuitry for controlling access to the array of memory cells;
wherein the array of memory cells comprises:
a plurality of shallow trenches filled with a dielectric material;
a plurality of columns surrounded by the plurality of shallow trenches;
a tunnel oxide layer at the top of each column;
a thick polysilicon floating gate over each tunnel oxide layer;
a set of spacers at an edge of each floating gate, the spacers over the dielectric material of the trenches;
a dielectric layer over the trenches, the spacers, and the floating gates; and
a control gate over the dielectric layer.

21. The non-volatile memory device of claim 20, wherein the floating gate is approximately 500-1500 Angstroms thick.

22. The non-volatile memory device of claim 20, wherein the spacers are formed of polysilicon.

23. The non-volatile memory device of claim 20, wherein the control gate is positioned over the floating gate.

24. The non-volatile memory device of claim 20, wherein the dielectric layer is patterned to control a coupling ratio between the floating gate and the control gate.

25. The non-volatile memory device of claim 20, wherein the dielectric layer has a thickness and width to control coupling between the floating gate and the control gate.

26. A memory device comprising:
an array of memory cells; and
control circuitry to read, write and erase the memory cells;
address circuitry to latch address signals provided on address input connections;
wherein the array of memory cells comprises:
a plurality of shallow trenches filled with a dielectric material;
a plurality of columns surrounded by the plurality of shallow trenches;
a tunnel oxide layer at the top of each column;
a thick polysilicon floating gate over each tunnel oxide layer;
a set of spacers at an edge of each floating gate, the spacers over the dielectric material of the trenches;
a dielectric layer over the trenches, the spacers, and the floating gates; and
a control gate over the dielectric layer.

27. The memory device of claim 26, wherein the floating gate is approximately 500-1500 Angstroms thick.

28. The memory device of claim 26, wherein the spacers are formed of polysilicon.

29. The memory device of claim 26, wherein the control gate is positioned over the floating gate.

30. The memory device of claim 26, wherein the dielectric layer is patterned to control a coupling ratio between the floating gate and the control gate.

31. The memory device of claim 26, wherein the dielectric layer has a thickness and width to control coupling between the floating gate and the control gate.

32. A processing system, comprising:
a processor; and
a memory coupled to the processor to store data provided by the processor and to provide data to the processor, the memory comprising:
an array of memory cells;
control circuitry to read, write and erase the memory cells;
address circuitry to latch address signals provided on address input connections;
wherein the array of memory cells comprises:
a plurality of shallow trenches filled with a dielectric material;
a plurality of columns surrounded by the plurality of shallow trenches;
a tunnel oxide layer at the top of each column;
a thick polysilicon floating gate over each tunnel oxide layer;
a set of spacers at an edge of each floating gate, the spacers over the dielectric material of the trenches;
a dielectric layer over the trenches, the spacers, and the floating gates; and
a control gate over the dielectric layer.

33. The processing system of claim 32, wherein the floating gate is approximately 500-1500 Angstroms thick.

34. The processing system of claim 32, wherein the spacers are formed of polysilicon.

35. The processing system of claim 32, wherein the control gate is positioned over the floating gate.

36. The processing system of claim 32, wherein the dielectric layer is patterned to control a coupling ratio between the floating gate and the control gate.

37. The processing system of claim 32, wherein the dielectric layer has a thickness and width to control coupling between the floating gate and the control gate.
